(19) United States
(12) Patent Application Publication
(10) Pub. No.: US 2011/0155689 A1
(43) Pub. Date: Jun. 30, 2011

(54) MORPHOLOGY DESIGN OF TRANSPARENT CONDUCTIVE METAL OXIDE FILMS

(75) Inventors: Yuting LIN, Hsinchu City (TW); Wenkai HSU, Zhubei City (TW); Shihche HUANG, Chiayi City (TW)

(73) Assignee: DU PONT APOLLO LTD., Pak Shek Kok (HK)

(21) Appl. No.: 12/980,850

(22) Filed: Dec. 29, 2010

Related U.S. Application Data
(60) Provisional application No. 61/291,229, filed on Dec. 30, 2009.

(51) Int. Cl. H01L 31/18; C09K 13/00; C09K 13/06; C09K 13/02

(52) U.S. Cl. 216/13; 252/79.1; 252/79.4; 252/79.5

(57) ABSTRACT

An etching paste suitable for etching films comprising an etchant and a component is provided. The etching process comprises applying the etching paste of the present invention to the transparent conductive metal oxide film by a paste application method so that the film is etched. Through the combination of the etching paste and the paste application method, the transparent conductive metal oxide film having stable scattering properties is obtained and can be used in the manufacture of a-Si solar cells.

### FIELD OF THE INVENTION

The present invention relates to an etching paste and a process of etching a metal oxide film for amorphous silicon solar cells by using the etching paste according to the present invention.

### BACKGROUND OF THE INVENTION

Amorphous silicon (a-Si) thin film solar cells are less expensive to produce and widely available, but have lower energy conversion efficiency. Therefore, in addition to an efficient way to keep the overall costs as low as possible, an effective method to improve the level of the energy conversion efficiency is needed.

Currently, a lot of new a-Si solar cells utilize transparent conductive metal oxide films which are conductors. These transparent conductive metal oxide films, for example, which are known to persons having ordinary skill in the art are indium-tin oxide (ITO), aluminum-doped zinc oxide (AZO) and fluorine-doped tin oxide (FTO). The transparent conductive metal oxide film allows light to pass through the window of a substrate on which the film is deposited to the light absorbing material beneath. In a-Si thin-film solar cells, the front sun-facing side of the a-Si solar cell can consist of the transparent conductive metal oxide films.

Structuring transparent conductive metal oxide films on a support substrate is important in the manufacture of a-Si solar cells. Chemical vapor deposition (CVD) such as atmospheric pressure chemical vapor deposition (APCVD) and wet etching is a common structuring technique. Using CVD is expensive, however, and wet etching has received much attention recently.

Two important process factors used in wet etching are concentration of the etching liquid and the etching time. By controlling the two factors, structures with different patterns can be obtained on the transparent conductive metal oxide films. However, when wet etching is applied in industrial manufacturing, some problems emerge.

A disadvantage of using an etchant in the aqueous form (or an etching liquid) relates to the fact that the etchant in the aqueous form cannot be confined to a desired area. When the etchant in the aqueous form flows on films to be etched, it is impossible to know how deep the etching is.

Furthermore, it is disadvantageous that a large number of process steps is necessary with use of expensive equipment. A lot of water and chemical agents need to be consumed as well.

US 2004/0063326 describes a method of etching a semiconductor substrate to produce solar cells. The method comprises applying a paste to the substrate and the paste is applied by screen-printing. US 2008/0217576 describes an etching medium for the structuring of transparent conductive metal oxide films and a process for the etching of transparent conductive oxide films using the etching medium applied by means of a printing process to the substrate to be etched in the production of thin-film solar cells.

However, there is still a need to provide a novel etching paste for use in etching films. The etching paste is used in a controlled way. There is also a need in the art to provide a novel and easily controlled etching process on the surface of transparent conductive metal oxide films so that the etched films have designed patterns thereon and suitable etching depths. The resulting etched films have stable scattering properties and can be used in the manufacture of solar cells which have better photoelectric transduction effect.

### SUMMARY OF THE INVENTION

The present invention provides an etching paste for use in etching films. Said etching paste comprises an etching agent which can be acid or base, and a component selected from at least one member of the group consisting of epoxy resin, polycarbonate, silicone, polyimide, polyaniline, polyethylene terephthalate, and combination thereof.

The present invention also provides an etching process on the surface of a transparent conductive metal oxide film. Said etching process comprises applying the etching paste of present invention to the transparent conductive metal oxide film by a paste application method so that the film is etched.

The present invention further provides a process for structuring a transparent conductive metal oxide film comprising applying the etching paste of the present invention to the transparent conductive metal oxide film by a paste application method so that the film is etched. The etched film can be used in the manufacture of a-Si solar cells.

### BRIEF DESCRIPTION OF THE DRAWING

FIG. 1 shows a protrudent structure on the surface of a film obtained by APCVD in the prior art.

FIG. 2 shows a hole structure on the surface of a film obtained by wet etching in the prior art.

FIG. 3 schematically shows a glass substrate with ZnO film before wet etching.

FIG. 4 schematically shows a cross-section view of a glass substrate with an etched ZnO film obtained by wet etching.

FIG. 5 schematically illustrates a process for etching a transparent conductive metal oxide film according to one embodiment of the present invention.

FIG. 6 schematically shows a cross-section view of a glass substrate with an etched transparent conductive metal oxide film obtained by the etching process according to one embodiment of the present invention.

FIG. 7 shows a top view of an etched film with a regular pattern according to one embodiment of the present invention.

FIGS. 8 and 9 show embodiments of mesh patterns according to the present invention.

FIG. 10 shows haze ratio of normal front electrode and patterned front electrode of a-Si solar cell.

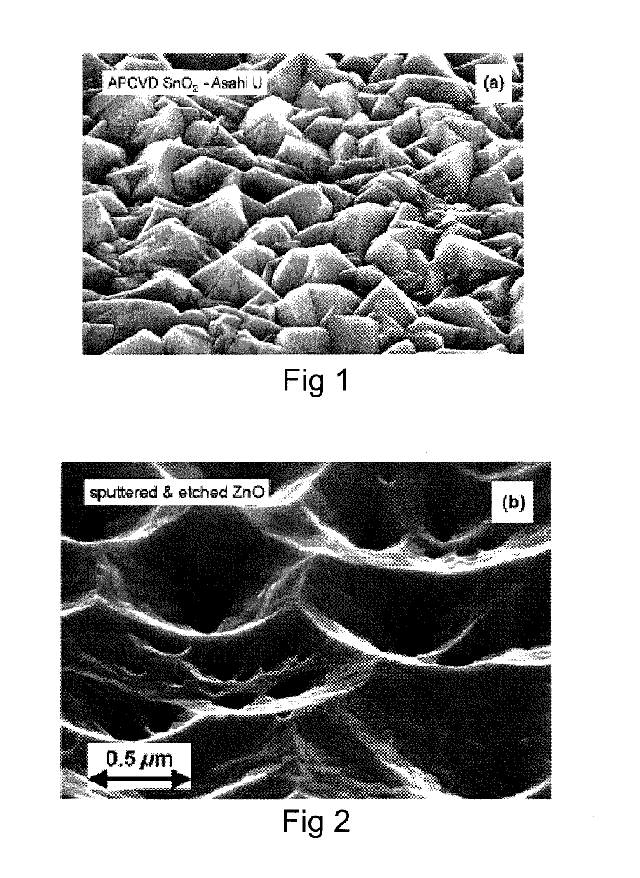

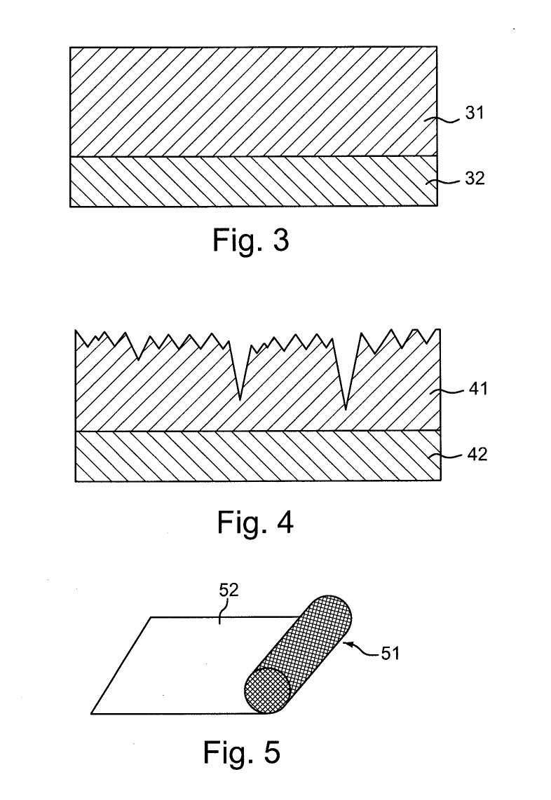

### DETAILED DESCRIPTION OF THE INVENTION

In the present invention, an etching paste suitable for etching films comprises an etchant and a component. The etching paste is basically used in an etching process on surface of a transparent conductive metal oxide film.

Suitable materials for the transparent conductive metal oxide film used in the present invention can be any metals known to persons having ordinary skill in the art for example, but not limited to, Ag, Al, Cu, Cr, Zn, Mo, Wo, Ca, Ti, In, Sn, or Ni. The transparent conductive metal oxide film can also be complex metal oxide films, which are known to persons having ordinary skill in the art for example, but not limited to, AZO(ZnO:Al), GZO(ZnO:Ga), ATO(SnO₂:Sb), FTO(SnO₂:F), ITO(In₂O₃:Sh), or BaTiO.

The etchant used in the present invention can be acid or base. Any acid or base known to be used in this field can be used in the present invention. Preferably, the acid used in the present invention is selected from the group consisting of H₃PO₄, HCl, CH₃COOH, HNO₃, and H₂SO₄, combination thereof, and derivatives thereof; the base used in the present invention is selected from the group consisting of NaOH, KOH, Na₂CO₃, and NH₃, combination thereof, and derivatives thereof.

The component used in the etching paste of the present invention is selected from the group consisting of epoxy resins, polycarbonate, silicone, polyimide, polyaniline, polyethylene terephthalate, and combination thereof.

The etching paste preferably has a viscosity which makes it to be applied in a controlled way. Therefore, the viscosity of the etching paste should be high enough to prevent flowing or spreading on the film. If the viscosity of the etching paste is not high enough, the paste will flow or spread in the subsequent steps and causes undesired patterns on the transparent conductive metal oxide films. The components used in the etching paste of the present invention can be selectively chosen by persons having ordinary skill in the art to adjust the viscosity of the etching paste so that it may be applied to the transparent conductive metal oxide films very accurately by the paste application method as mentioned herein and be confined to a desired area. After application, the etching paste will not spread or flow significantly on the films because of its viscosity.

In an aspect of the invention, an etching process on the surface of a transparent conductive metal oxide film comprises applying the etching paste according to the present invention to the metal oxide film by a paste application method so that the film is etched. Through the combination of the etching paste and the paste application method, the transparent conductive metal oxide film having stable scattering properties is obtained, and thus can be used in the manufacture of a-Si solar cells.

The paste application method used in the present invention can comprise, but is not limited to, a rolling method. It is advantageous that the skilled person can design any suitable patterns on the roller used in rolling method. Therefore, the pattern on the transparent conductive metal oxide film can be various and the film can be formed with any suitable and desired patterns. In a rolling screen-printing system, the conveyer carries the glass with a transparent conductive metal oxide film to the rolling coating zone, followed by coating the etching paste on the transparent conductive metal oxide film. The resulting etched film has structures with regular patterns on the surface by designing patterns on the roller. The remaining etching paste on the etched transparent conductive metal oxide film is washed out in the cleaner.

In a preferred embodiment, the pattern on the roller used in the rolling method can comprise, but is not limited to, patterns with openings. The openings can be circular openings, rectangular openings, linear or non-linear openings for example, stripe-like openings, or any other type of openings.

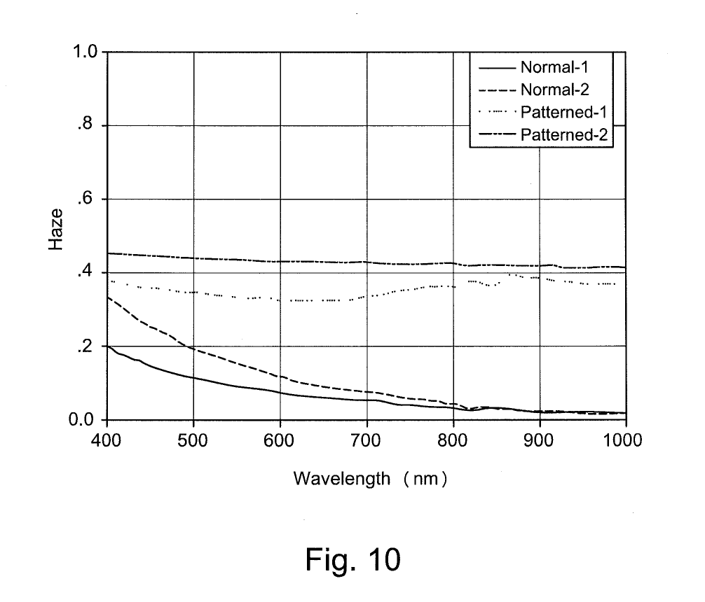

In a preferred embodiment, the pattern on the roller used in the rolling method can comprises, but is not limited to, circles, or ellipses, or polygons with n sides, wherein n is, for example, 3, 4, 5, 6, or 8. More importantly, the pattern on the roller is orderly arranged so that the etched films have regular patterns thereon. Referring to FIG. 10, the curves indicated as Normal-1 and Normal-2 show that the haze ratio resulted from the patterned surface with an irregular pattern decreases while the wavelength increases. In contrast, the curves indicated as Patterned-1 and Patterned-2 show that the haze ratio resulted from the patterned surface with a regular pattern does not decrease while the wavelength increases.

In a preferred embodiment, the pattern can comprise, but is not limited to, rhombus or hexagonal patterns.

In a preferred embodiment, the pattern has an opening size ranging from 5 to 20 μm.

The etching depth is important to the transparent conductive metal oxide film used in the manufacture of a-Si solar cells. If the etching depth is over 500 nm, the grooves on the film will not be filled with the light-absorbing lay, which results in reduction of yield. In a preferred embodiment, the transparent conductive metal oxide film etched by the process according to the present invention has an etching depth ranging from 100 to 500 nm.

The combination of an etching paste and a paste application method of the present invention can avoid over-etching the transparent conductive metal oxide film, greatly reducing the variation of the surface morphology of the transparent conductive metal oxide film. Thus, the present invention overcomes the drawbacks of forming a film with inconsistent physical properties.

For better understanding, the present invention is illustrated below in details by an embodiment with reference to the drawings, which are not intended to limit the scope of the present invention. It will be apparent that any modifications or alterations that can easily be accomplished by those having ordinary skill in the art fall within the scope of the disclosure of the specification.

FIG. 5 schematically illustrates a process for etching a transparent conductive metal oxide film according to one embodiment of the present invention. Before etching the transparent conductive metal oxide film 52, the skilled persons can design a pattern on a roller 51. As shown in FIG. 5, an etching paste is applied to the roller 51 and then the transparent conductive metal oxide film 52 is patterned and etched by using the roller 51. In the process of the present invention, the persons having ordinary skill in the art can select suitable types of the rollers and decide suitable operation conditions, depending on the needs. For example, the conveyer speed is about 0.5 to 6 m/s. The rolling speed of the roller is about 10 to 300 rpm. The press amount is about 0 to 2 mm. The etching temperature is about 25 to 60° C., the cleaning temperature is about 25 to 30° C., and the drying temperature is about 60° C.

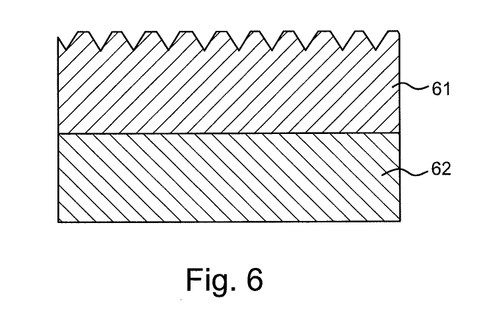

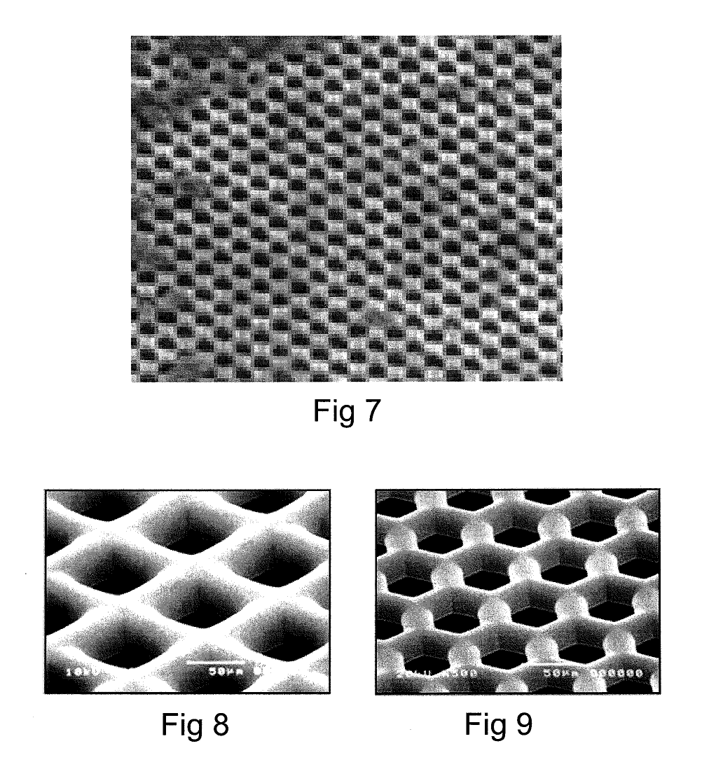

FIG. 6 schematically shows a cross-section view of an etched transparent conductive metal oxide film 61 on a glass substrate 62 which is obtained by the etching process according to one embodiment of the present invention. Compared with FIG. 4, the etched transparent conductive metal oxide film 61 in FIG. 6 has the desired pattern and a controlled etching depth. FIG. 7 shows a top view of an etched film with a regular pattern obtained by the process of the present invention.

In a preferred embodiment of the present invention, the patterns on the transparent conductive metal oxide films can be various because it is easy to design the patterns on the roller used in the present invention. When the paste application method is a rolling method, skilled persons can design different patterns, for example, as those shown in FIGS. 8 and 9. FIG. 10 shows that the patterned surface of the transparent conductive metal oxide film will increase the haze ratio and has longer light path which makes the a-Si solar cell gain more efficiency.

Although the present invention has been described with reference to the illustrative embodiment, it should be understood that any modifications or alterations that can easily be accomplished by persons having ordinary skill in the art will fall within the scope of the disclosure of the specification, drawings, and the appended claims.

What is claimed is:

1. An etching paste for use in etching films, comprising:
an etchant, which is acid or base; and
a component comprises at least one member selected from the group consisting of epoxy resin, polycarbonate, silicone, polyimide, polyaniline, polyethylene terephthalate, and combination thereof.

2. The etching paste of claim 1, wherein the acid is selected from the group consisting of H₃PO₄, HCl, CH₃COOH, HNO₃, and H₂SO₄, combination thereof, and derivatives thereof.

3. The etching paste of claim 1, wherein the base is selected from the group consisting of NaOH, KOH, Na₂CO₃, and NH₃, combination thereof, and derivatives thereof.

4. A process for etching a transparent conductive metal oxide film comprising applying the etching paste according to claim 1 to the transparent conductive metal oxide film by a paste application method so that the film is etched.

5. The process of claim 4, wherein the etching paste is applied to the film to form a pattern.

6. The process of claim 4, wherein the paste application method comprises a rolling method.

7. The process of claim 6, wherein the rolling method uses a roller having patterns.

8. The process of claim 7, wherein the patterns comprise pattern with openings.

9. The process of claim 8, wherein the pattern has an opening size ranging from 5 to 20 μm.

10. The process of claim 4, wherein the etched film has an etching depth ranging from 100 to 500 nm.

11. A process for structuring a transparent conductive metal oxide film comprising applying the etching paste according to claim 1 to the transparent conductive metal oxide film by a paste application method so that the film is etched.
